(19) United States
(12) Patent Application Publication
(10) Pub. No.: US 2002/0180890 A1
(43) Pub. Date: Dec. 5, 2002

(54) Modular digital television architecture

(76) Inventors: James R. Milne, Ramona, CA (US); Michael D. McDermott, San Diego, CA (US)

Correspondence Address: FITCH EVEN TABIN AND FLANNERY, 120 SOUTH LA SALLE STREET, SUITE 1600, CHICAGO, IL, 60603-3406, US

(21) Appl. No.: 09/862,391

(22) Filed: May 21, 2001

(51) Int. Cl. H03M 1/12

(52) U.S. Cl. 348/572

(57) ABSTRACT

A modular digital television architecture and method of designing the same is disclosed. The television architecture includes a processing chassis module operative to convert an analog input signal into at least a first digital signal for use in providing information to a display; a presentation chassis module operative to convert audio and visual components of the at least first digital signal into a final signal for presentation on the display, the audio and visual conversion being performed in a first domain; and an interface operative to interconnect the processing chassis module and the presentation chassis module. The processing and presentation chassis module are designed and operate independently of one another. The interface is a global interface capable of being used in conjunction with a plurality of chassis architectures. By employing a modular design, a variety of digital television systems can be readily produced.

### FIELD OF THE INVENTION

The present invention generally relates to digital televisions and, more particularly, to a system and corresponding method for providing a family of digital televisions based on a modular system architecture.

### BACKGROUND OF THE INVENTION

The design of conventional television systems requires the hardware components of the system to be completely designed before the software is developed for a given design. After the hardware design has been completed and certified, the software protocols implemented to perform the functionality of the particular system design are then developed. Thus, conventional television designs require a grouping of protocols to a specific hardware configuration.

Due to the one-to-one correspondence between the hardware and software, any change in the hardware design will result in the need to develop entirely new software protocols corresponding to the changed or otherwise revised, hardware design. Thus, interchanging or coupling a particular hardware design with a particular software protocol not originally developed for such hardware design is not possible. Consequently, the ability to upgrade or enhance the operational capabilities of a hardware design with new software is not possible.

Structurally, conventional television designs employ an architecture where audio and video signal processing and filtering operations are performed throughout the entirety of the system. Often times, the design of television systems are made more complex by the type and physical location of the components that perform the signal processing operations. Further adding to system complexity is the large amount of data that must be transferred between the processing elements. Due to the data transfer and signal processing constraints described above, conventional digital television designs generally require the use of two or more microcontrollers to carry out the necessary data transfer and signal processing operations. This results in the software used to control television system operation becoming increasingly complex and difficult to coordinate. The more complex the required software, the longer it takes to develop and debug the software. Consequently, the price of any resulting digital television system increases dramatically.

### SUMMARY OF THE INVENTION

The aforementioned and related drawbacks associated with conventional digital television system development have been substantially reduced or eliminated by the modular digital television architecture of the present invention. The present invention is directed to a digital television system implemented with modular components that are fully interchangeable. By employing a modular architecture, families of digital televisions, each having different and/or specific functionality can be implemented. Under the modular architecture approach, the processing chassis module and presentation chassis module of the digital television are developed and implemented independently of one another. A global interface, that works in conjunction with several types of chassis architectures, is used to interconnect the corresponding processing and presentation chassis modules. In this fashion, a family of digital televisions can be created through interchanging various combinations of processing and presentation chassis modules with the global interface.

Accordingly, in an exemplary embodiment of the present invention, the digital television includes a processing chassis module operative to convert an analog input signal into a least a first digital signal for use in providing information that is to be later displayed by a presentation module, the processing chassis module including a dedicated power source and a processing element; a presentation chassis module operative to convert the audio and visual components of the at least first digital signal into a final signal for presentation on a display device, the audio and visual conversion being performed in a first domain, the presentation chassis module being separate from the processing chassis module and including a dedicated power source, the power source of the presentation chassis module being different from and operating independently of the power source of the processing chassis module; and an interface which provides a communication path between the processing chassis module and the presentation chassis module. In an exemplary embodiment, the power source used in the processing chassis module is independent of the power source used in the presentation chassis module. In this fashion, the two chassis modules are not physically dependent upon one another for power.

An advantage of the present invention is that the modular architecture is straightforward to implement and can be used to create a family of products.

Another advantage of the present invention is that it provides for faster product development time.

Yet another advantage of the present invention is that the modular architecture can be implemented at low cost.

A feature of the present invention is that the modular architecture provides for easy upgrade ability.

Another feature of the present invention is that the digital television exhibits improved performance characteristics as compared to conventional television designs.

### BRIEF DESCRIPTION OF THE DRAWINGS

The aforementioned and related advantages and features of the present invention will become apparent upon review of the following detailed description of the invention, taken in conjunction with the following drawings, where like numerals represent like elements, in which:

FIG. 1 is a block diagram of the overall architecture of the digital television system of the present invention;

FIG. 2 is an exploded schematic view of the components that comprise the legacy block of the processing chassis module which is responsible for digitizing and up conversion of the analog input signals to the digital television;

FIG. 3 is a schematic block diagram of the components that comprise the processing chassis module of the digital television illustrated in FIG. 1;

FIG. 4 is a block diagram of the interface architecture used to interconnect the processing chassis module and the presenting chassis module of the digital television according to an exemplary embodiment of the present invention; and

FIG. 5 is a schematic block diagram of the presentation chassis module of the digital television according to an exemplary embodiment of the present invention.

### DETAILED DESCRIPTION OF THE INVENTION

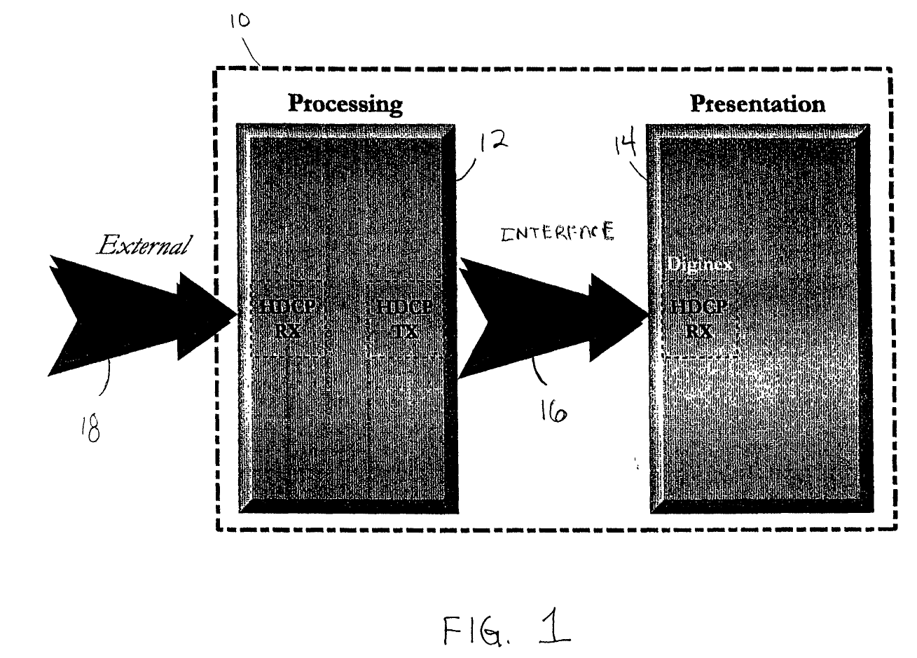

The modular digital television architecture and method of implementing the same will now be described with reference to FIGS. 1-5. FIG. 1 is a block diagram of the overall architecture of the digital television of the present invention. As illustrated in FIG. 1, the digital television (DTV) 10 includes a processing chassis module 12, a presentation chassis module 14 and an interface 16 that is operative to interconnect and provide a communication path between the processing chassis module 12 and the presentation chassis module 14.

The processing chassis module 12 is operative to convert an analog input signal provided by an external source 18 (such as an antenna, a cable connection or a satellite feed) into at least a first digital signal before the audio and visual information contained within the first digital signal are presented to the user on a suitable display device (not shown). The display device can be a CRT or a suitable type of digital display device. In an exemplary embodiment, the display device is implemented as a CRT. The signals generated by the processing chassis module 12 are transmitted through the interface 16 to the presentation chassis module 14. The corresponding CRT (or other display device) operates under the control of the presentation chassis module 14.

In an exemplary embodiment of the present invention, the interface 16 is a Digital Video Interface (DVI) that operates according to the DVI 1.0 specification promulgated by the Digital Display Working Group (DDWG), which is incorporated fully herein. The DVI interface 16 can be used in conjunction with a variety of chassis (i.e. digital component) modules to provide a high speed digital connection for visual data types that is display technology independent. In an alternate embodiment, the interface 16 is a digital interface operating according to the EIA 861 standard promulgated by the Consumer Electronics Association (CEA).

The presentation chassis module 14 includes all of the necessary components used to filter the incoming digital signals and to display the video images contained within the digital signals, and receive and play audio recordings. The audio and video information presented to the user by the presentation chassis module 14 are provided thereto by the interface 16.

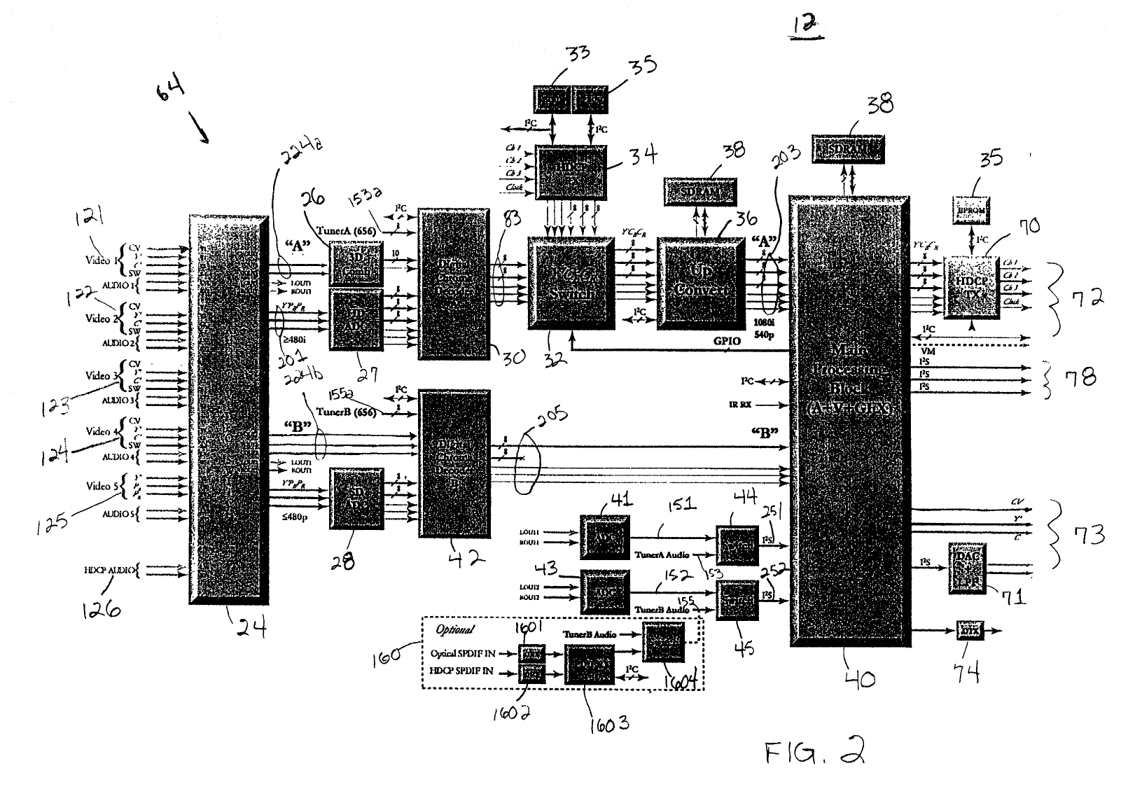

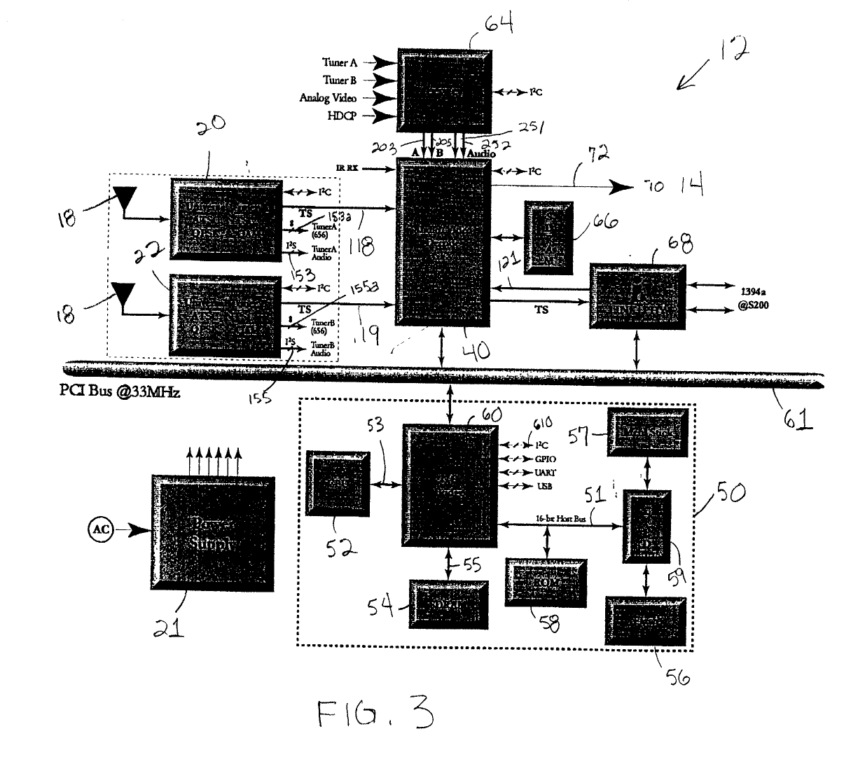

The processing chassis module 12 will now be described with reference to FIGS. 2 and 3. The processing chassis module 12 is responsible for converting the analog input signal(s) received by the external source 18 (FIG. 1) into at least a first digital signal which includes both the audio and video information contained in the input signal(s). Initially, the analog input signal(s) are digitized and up converted to an appropriate digital format by a legacy block 64 (FIG. 3). The digital signals are then transmitted to and processed by the main processing block 40 of the processing chassis module 12. For purpose of description and identification, the components to the left of the main processing block 40 comprise the legacy block 64. In an exemplary embodiment of the present invention, the audio and video information is provided to the main processing block 40 on two channels, referred to as channel A (“A”) and channel B (“B”), respectively. The particular channel that the audio and video information is provided on is determined by audio/visual (A/V) switch 24.

Referring to FIG. 2, the video processing section of the processing chassis module 12 will now be described. As shown, the input audio and video signals (121-126) are provided as inputs to the A/V switch 24. The A/V switch 24 controls whether the resulting output signals are provided on channel A or channel B. For example, FIG. 2 illustrates the information present on Video line 1 121 being provided on channel A while the video information present on Video line 4 is provided on channel B. For purposes of clarity, channel A processing will be described first; then channel B processing will be described.

The input signals 121-125 of the A/V switch 24 are received by the external source 18 (FIG. 1) and comprise composite video signals. The information present on line 126 is comprised of high definition audio signals. More specifically, the video information 121-125 is embodied in four types of signals: (1) standard composite video signals (CV); (2) S-video information, such as provided by DVD media (Y and C); and (3) S-video identification information (SW). Each of these signals are provided as inputs to the A/V switch 24, which provides a corresponding subset of the signals on channel A (lines 224a). The determination of which signals are provided on a given channel is determined, in part, on the identification information present on line SW. The audio information present, for example, on line 121 is provided by the A/V switch 24 on audio lines LOUT1 and ROUT1.

Video line 5 125 is comprised of component video signal information. Depending on the state of the A/V switch 24, the component video signals are transmitted to a high definition analog-to-digital converter (ADC) 27 on line 201.

Referring back to the composite video signals (CV, Y and C), these signals are transmitted to a 3D Comb filter 26 from the A/V switch 24. The 3D Comb filter 26 operates to separate the luminance (brightness) and chrominance (color) information from the input signals. The resulting brightness and color information, along with command information present on line I²C and video type (ITU BT.656) information from front end tuner module 20 (FIG. 3) on line 656, is transmitted to a first chroma decoder 30.

The first chroma decoder 30 decodes the corresponding brightness, color and video information from the video signals input thereto. Such decoding includes the detection of closed captioning, wide screen, V-chip and other video presentation information transmitted by the input signals. The output of the first chroma decoder 30 is either a standard resolution (480i) NTSC signal or a higher resolution (≧480p) NTSC signal.

After the input video signals have been decoded and digitized by the first chroma decoder 30, the resulting digital video signals are then transmitted on line 83 as inputs to a component video (Y'C_{B}C_{R}) switch 32. Additional inputs to the component video switch 32 are provided by a High Bandwidth Digital Content Protection (HDCP) receiver 34. Inputs to the HDCP receiver 34 include system command information on line I²C, video channel information on lines Ch1-Ch3 and system clock (Clock) information. The command information is comprised of, for example, monitor identification type information maintained in the Extended Data Identification Module (EDID) 33 and any encryption keys. The encryption keys are stored in EPROM memory 35. The output of the HDCP receiver 34 can be comprised of either high definition or standard definition component video signals. Accordingly, a first subset of inputs to the component video switch 32 consists of digitized component video signals. A second subset of inputs consists of digital component video signals from the HDCP receiver 34. Based on the inputs provided thereto, the component video switch 32 will transmit either the digitized component video signals or digital component video signals to an up converter 36 for further processing.

The up converter 36 converts the video signals provided by the component video switch 32 into corresponding output signals as illustrated in Table 1 below.

TABLE

| Input Signal | Output Signal |
|---|---|
| 480i | 1080i |
| 480p | 540p |
| 720p | 540p or 1080i |
| 1080i | 1080i |

As shown in Table 1, a 480i input signal will be converted into a 1080i signal; a 480p input signal will be converted into a 540p signal; and a 720p input signal will be converted into either a 540p or a 1080i signal. A 1080i input signal will pass unchanged through the up converter 36. In application, the 480p video signal is a higher resolution signal as compared to a standard 480i signal.

The up converter 36 includes a corresponding memory (SDRAM 38) which stores the digitized information, referred to as digital reality creation signals, of the up converter 36. After being converted, the video signals are then transmitted to the main processing block 40 on line 203. The processing of the signals transmitted to the main processing block 40 will be described in greater detail below with reference to FIG. 3.

The video signals provided on channel B will now be described. The processing chassis module 12 employs a second chroma decoder 42, similar in structure and operation to first chroma decoder 30, to decode and digitize the corresponding input video signals (i.e., Video 1 121, Video 2 122, Video 3 123, Video 4 124 and Video 5 125) provided on channel B by the A/V switch 24. In an exemplary embodiment, the video signals transmitted on channel B are only 480i and 480p signals. Thus, after the input video signals have been decoded and converted into digital format by the second chroma decoder 42, they are transmitted directly into the main processing block 40 on line 205 for further processing. In operation, the second chroma decoder 42 is used to digitize the second picture of a twin picture function. As used herein, the twin picture is defined to mean adjacent picture information which may be present on video input lines 121-124.

Additionally, the video signals provided by the A/V switch 24 on channel B are standard definition (≦480p) signals. These standard definition signals are converted into digital signals by the standard definition ADC 28 before being transmitted to the second chroma decoder 42 for processing.

The audio processing section of the processing chassis module 12 will now be described. As illustrated in FIG. 2, audio signals from the various front panel channels (121-125) are provided to the A/V switch 24 on corresponding audio lines (Audio 1-Audio 5). High definition audio signals are transmitted to the processing chassis module 12 from the external source 18 (FIG. 1) on line 126. The analog audio signal information is provided by the A/V switch 24 on corresponding lines LOUT1-LOUT2 and ROUT1-ROUT2.

Audio signals LOUT1 and ROUT1 are provided as inputs to an ADC 41. The digital output signal provided by the ADC 41 on line 151 is provided as the first input to a first audio switch 44. The second input to the first audio switch 44 is provided by a direct tuner audio on line 153. The output of the first audio switch 44 is then transmitted to the main processing block 40 on line 251 for further processing.

Audio signals LOUT2 and ROUT2 are provided as inputs to an ADC 43. The digital output signal provided by the ADC 43 on line 152 is provided as the first input to a second audio switch 45. The second input to the second audio switch 45 is provided by direct tuner audio on line 155. The output of the second audio switch 45 is transmitted to the main processing block 40 on line 252 for further processing.

In an alternate embodiment, the second input to the second audio switch 45 is provided by the output of a digital audio module 160. The digital audio module 160 is comprised of a plurality of input receivers 1601 and 1602. The input of first input receiver 1601 is provided by an optical analog input (SPDIF IN). The input to the second input receiver 1602 is provided by a secondary digital audio input signal (HDCP SPDIF IN). The corresponding outputs of the receivers 1601 and 1602 are provided as inputs to a receiver 1603. A third input to the receiver 1603 is provided by a control signal on line I²C. The output of the receiver 1603 is provided as a first input to switch 1604. The other input to switch 1604 is provided by tuner A or B audio. In the alternate embodiment, the output of the switch 1604 replaces the direct audio from tuner B on line 155. In a second alternate embodiment, the output of the switch 1604 replaces the direct audio from tuner A on line 153.

After a suitable level of processing has been performed on the audio input signals present on lines 251-252, the processed audio data is provided by the main processing block on line 78. Other output signals provided by the main processing block 40 include monitor output line 73. The output signals present on line 73 are down converted to 480i format and then transmitted to a video cassette recorder (VCR), or other suitable device, for later playing or recording.

The processed digital video signal information, whether on channel A or channel B, are transmitted to a high definition transmitter 70. Other data transmitted to the transmitter 70 include signals from the (optional) front-end tuners 20, 22 on lines 118 and 119, respectively (FIG. 3) and data from the i.LINK module 68 on line 121 (FIG. 3). The transmitter 70 then encrypts the digital video data, if necessary, based on encryption key data present in memory unit (EPROM) 35. The digital video data is then provided on corresponding channel lines Ch1-Ch3. The digital video signals on lines Ch1-Ch3, the command control line I²C and the information present on analog signal line VM are all transmitted to the presentation chassis module 14 on line 72 via the interface 16.

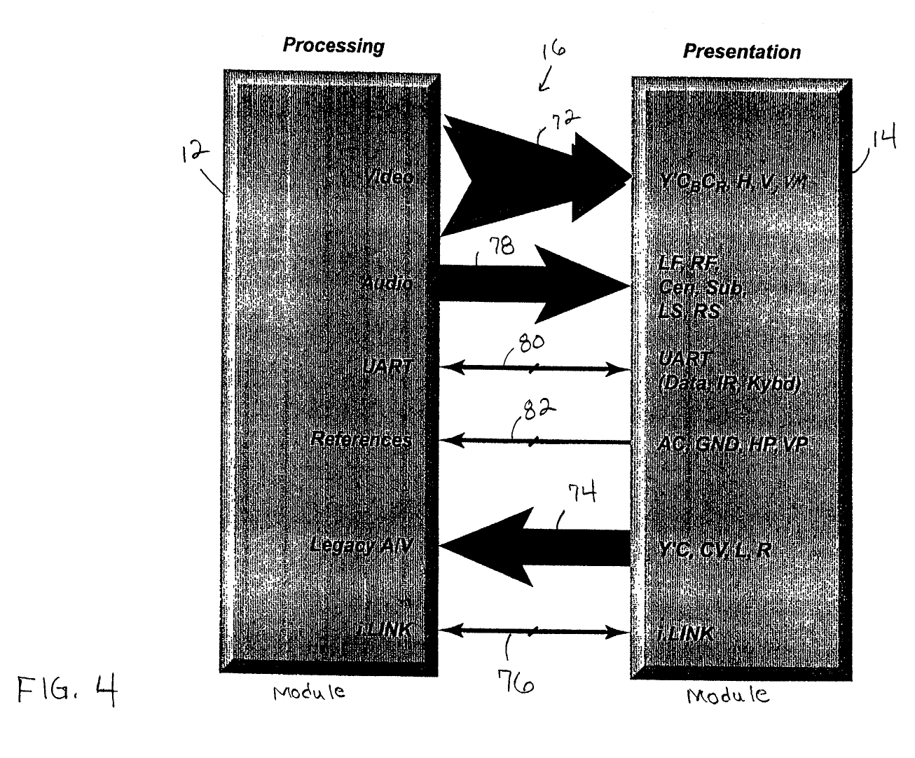

FIG. 3 is a schematic block diagram of the components that comprise the processing chassis module of the present invention. The processing chassis module 12 includes a processor section 50 including a central processing unit (CPU) 52, an SDRAM 54, a flash memory 56, a read only memory (ROM 58) and an I/O Bridge 60. An optional memory stick interface 57 and CMOS programmable logic device (CPLD) 59 are also shown. The ROM 58 is connected to the I/O Bridge 60 through a processor bus 51. The flash memory 56 of the processor section 50 is also coupled to the processor bus 51 via CPLD 59. The SDRAM 54 is connected to the I/O Bridge 60 via a dedicated bi-directional line 55. Other inputs to the I/O Bridge 60 include information contained on a I²C line 610 which is used to transfer basic communication signals, a USB connection, general purpose I/O lines (GPIO) as well as an UART line 80 (FIG. 4) which is used to transfer control information between the chassis modules. The CPU 52 executes the protocols stored in either the flash memory 56 or the ROM 58. The CPU 52 acts as an overall system (digital television) controller.

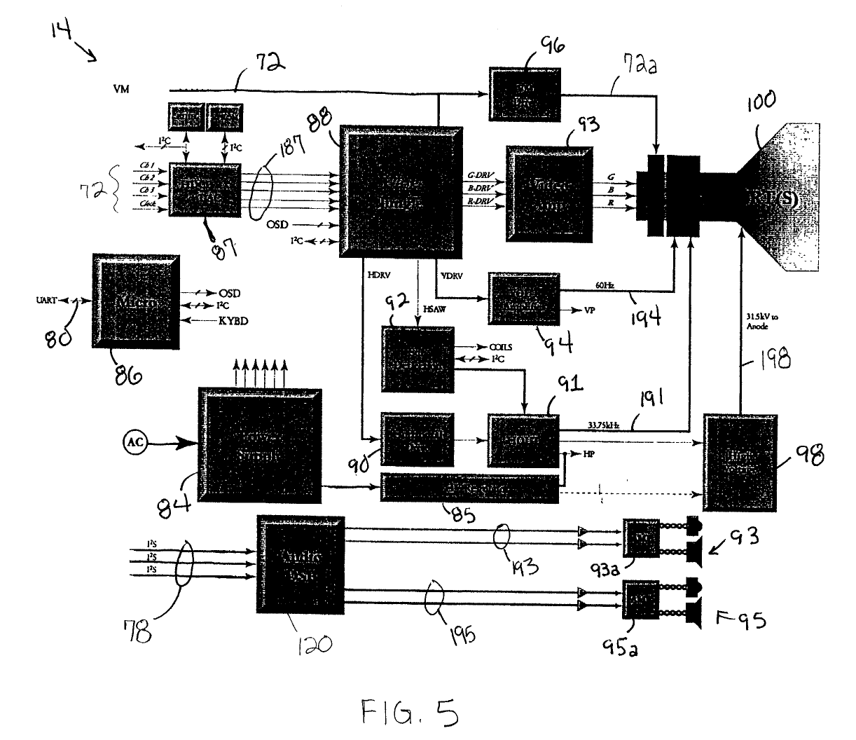

The main processing block 40, in an exemplary embodiment, is also an MPEG module that generates the video images that are presented on the display 100 (FIG. 5) based on the signals input thereto according to the specifications promulgated, for example, by the Motion Picture Expert Group. The output of MPEG module 40 is provided to the presentation chassis module 14 via line 72. Other inputs to the MPEG module 40 include a signal from a front end ATSC tuner module 20 operating in accordance with the specification promulgated by the Advanced Television Systems Committee (ATSC). The ATSC tuner module 20 transmits an ATSC signal into the main processing block 40 on line 118. Another input to the MPEG module 40 is provided by an optional front end DirecTV™ and Smart Card module 22, which transmits a satellite signal into the main processing line 40 on line 119. The DirecTV™ and Smart Card module 22 is also connected to the MPEG module 40 via bi-directional line 120. Also shown in FIG. 3 is an i.LINK signal on line 121 being provided as an input into the MPEG module 40 of the main processing block 40. The i.LINK signal is generated by an i.LINK element 68. The i.LINK element 68 transmits a signal from the front panel of the digital television system 10 to the i.LINK module located within the processing chassis module 12.

Power for both the video processing section and the audio processing section of the processing chassis module 12, as well as the main processing block 40, is provided by a dedicated low voltage power supply 21. In operation, the low voltage power supply 21 generates substantially about 0.5W of power.

One of the objectives of the processing chassis module 12, is to transmit all of the audio and video information provided by the respective tuners and decoders into the main processing block 40 as quickly as possible, while at the same time minimizing the number of domain changes that need to be performed on the input signals. For purposes of the present invention, domain changes refer to the number of times a signal has to be converted from analog-to-digital or digital-to-analog. As illustrated in FIG. 2, such domain changes are minimized by having the input audio and video signals being converted from one domain (analog) to another domain (digital) only once by the high definition ADC 27 and/or the corresponding standard definition ADC 28.

In operation, the analog audio and video signal information are received by the external source 18 (FIG. 1) and are transmitted into the processing chassis module 12 via the A/V switch 24. The A/V switch 24 then transmits corresponding audio and video information on either a first channel (Channel A) or a second channel (Channel B). In an exemplary embodiment, video data ≧480i is transmitted on Channel A. Standard definition video data (≦480p format) is transmitted on Channel B. The brightness and color information contained within the video signals is separated by the 3D Comb 26 and then decoded and digitized by the first chroma decoder 30. The video information on Channel A is then converted into a digital signal, for processing, by the ADC 27. The video information is then transmitted to a component video switch 32, which provides either the standard definition video signal or a corresponding high definition video signal to an up converter 36.

If the signal provided by the component switch 32 is a standard definition video signal, such signal is converted into a higher definition (540p or 1080i format) video signal by the up converter 36. The resulting video signal is then transmitted to the main processing block for processing. If the signal provided by the component switch 32 is a high definition video signal, such signal passes directly through the up converter 36 to the main processing block 40 without being changed. An exception to the direct passage scheme described above occurs when the signal provided by the component video switch 32 is a 720p format signal (see Table 1). In such a situation, the 720p format signal is converted to either a 540p or a 1080i signal.

In corresponding fashion, video signals present on Channel B which are already in standard definition (≦480p) format, are digitized by the second chroma decoder 42 and transmitted directly to the main processing block 40 for processing. The audio signals received by the external source 18 (FIG. 1) are transmitted to the main processing block 40 for processing after first being converted into digital format by associated ADC's 41 and 43, respectively. The processed audio signals are then provided to corresponding audio delivery components (e.g. speakers) which are capable of delivering sounds to a user.

Upon being received in the main processing block 40, the digital video input signals are representative of the video images that are presented on the display device based on a particular protocol. The output of the main processing block 40 is then transmitted to the interface 16 on transmission line 72. As illustrated in greater detail in FIG. 2, the video transmission line 72 is comprised of the digital video data present on Ch1-Ch3, the system clock (Clock), line VM and the control signal I²C.

The interface 16 used in the digital television 10 of the present invention will now be described with reference to FIG. 4. As discussed above, the interface 16 operates according to the DVI 1.0 specification promulgated by the DDWG. Accordingly, the interface 16 is a global interface that can be used in conjunction with several different types of chassis modules and architectures. In application, the interface 16 is comprised of a series of transmission lines that provide a communication path between the processing chassis module 12 and the presentation chassis module 14. As shown in FIG. 4, the interface 16 includes video signal transmission lines 72 that transfer digital video information signals from the main processing block 40 of the processing chassis module 12 to the presentation chassis module 14. Audio line 78 provides the audio information (i.e. left audio, right audio, etc.) to the presentation chassis module 14. Bi-directional UART line 80 transfers basic communication information, received infrared commands and push button commands from the front panel of the display in addition to the corresponding reference signals between the two chassis modules. Reference line 82 transmits power, ground and additional timing information from the presentation chassis module 14 to the processing chassis module 12. Legacy signal line 74 and bi-directional i.LINK line 76 transfer the front panel information between the presentation chassis module 14 and the processing chassis module 12.

According to the present invention, the interface 16 uses transition minimized differential signaling (TMDS) for the base electrical interconnection between the processing chassis module 12 and the presentation chassis module 14. The transition minimization can be achieved, for example, by implementing an advanced encoding algorithm that converts 8-bits of data into a 10-bit transition minimized, dc balanced character. According to an exemplary embodiment, the interface 16 of the present invention employs a physical structure including a transmitter (not shown) which incorporates an advanced coding algorithm to enable TMDS signaling which reduces the electromagnetic interference across the aforementioned transmission lines. The presentation chassis module 14 will now be described with reference to FIG. 5.

The presentation chassis module 14 includes a display 100 and at least a pair of speaker units 93 and 95, respectively, operative to present video and audio information to a user. In an exemplary embodiment, the display 100 is a CRT display, that is operative to present the video information based on the signals generated by the processing chassis module 12 and transferred through the interface 16. In addition to being a CRT display, the display 100 can be any of the digital display devices presently available on the market. The display 100 includes a front panel (not shown) having a plurality of buttons that are used to adjust the characteristics of the video and audio information presented to the user. The presentation chassis module 14 further includes a processor 86, which transmits and receives signals from the UART line 80. The microprocessor 86 is used to process and transmit information, for example, from the front panel of the display 100 to the processing chassis module 12.

An HDCP receiver 87, including a digital-to-analog converter (DAC) converts the input digital video signals on lines Ch1-Ch3 (from main processing block 40) into analog signals on lines 187. The analog signals are transmitted to display capture hardware 88 for further processing. Display capture hardware 88, provides for the proper timing of the received signals for presentation on the display device 100. In operation, the display capture hardware 88 receives the analog signals on lines 187 from the HDCP receiver 87 and synchronizes the analog signals, and then performs optional final color matrix conversion, brightness, hue and contrast processing operations on the received signals. It should be noted that the aforementioned brightness, hue and contrast processing operations could also be performed in the processing chassis module 12. A first subset of the processed signals are transmitted to the horizontal timing circuitry (HOUT) 91 via the horizontal controller circuitry 90 for presentation of properly adjusted horizontal component video signals to the display device 100. A second subset of the processed signals are transmitted to the vertical timing and amplifier circuitry (VOUT) 94 for presentation of properly adjusted vertical component video signals to the display device 100. A third subset of processed signals is transmitted to sub-deflection circuitry 92 for additional processing before being provided as an input to the horizontal output circuitry 91.

After being processed in the display capture hardware 88, the remaining signals are amplified by the video amplifying circuitry 93 before being presented to and displayed on the display device 100. The output of the video amplifier 93 are the Green (G), Blue (B) and Red (R) pixel signals that form the image displayed on the display device 100. The vertical (VOUT) and horizontal (HOUT) control signals corresponding to the resulting image are provided by the VOUT 94 and HOUT 91 circuitry on lines 194 and 191, respectively. As further illustrated in FIG. 4, the velocity module (VM) video signal is transmitted directly from the processing chassis module 12 into the VM drive 96. The output of the VM drive 96 is transmitted to the control section of display device 100 for incorporation into the composite signal that is displayed to the user. The audio signals transmitted from the processing chassis module 12 on lines 78 are processed by the audio digital signal processing (DSP) chip 120 and then provided to the speaker units 93, 95 for presentation to the user. For example, the audio to be provided by speaker unit 93 is transmitted thereto on line(s) 193. The audio to be provided by speaker unit 95 is transmitted thereto on line(s) 195.

The presentation chassis module 14 also includes a dedicated high voltage power supply 84 that provides the necessary power to the components maintained within the module. For example, power is transmitted from the power supply 84 to the display device 100 through a pair of high voltage regulation components 85 and 98, respectively. In an exemplary embodiment, the power supply 84 provides between 5W-1 kW of power to the components of the presentation chassis module 14. It is important to note that the power supply 84 of the presentation chassis module 14 is separate from and operates independently of the low voltage power supply 21 used in the processing chassis module 12. The power supply 84 of the presentation chassis module needs to be separate from the low voltage power supply 21 of the processing chassis module 12 because the presentation chassis module never knows what type of processing chassis module it is interfacing with. Thus, by providing for independence of operation, the processing and presentation chassis modules of the present invention can be interconnected in any suitable combination.

Based on the above discussion, it will become apparent that the processing chassis and presentation chassis modules can be designed independently of one another. Moreover, as the processing chassis and presentation chassis modules can operate independently of one another, families of digital televisions can be created through the interchanging of various combinations of processing and presentation chassis modules with the global interface. For example, through the modular television architecture of the present invention, it is possible to match different types of processing chassis modules (e.g. based on functionality) with a single presentation chassis module. Thus, a family of digital televisions can be made available based on functionality or performance. Moreover, upgrading a particular digital television can be performed by simply exchanging one module with another module. This provides the digital television manufacturer with a powerful development tool as presentation chassis development is generally slower than processing chassis development. Correspondingly, when a new or upgraded presentation chassis module is available, it can be matched with any number of processing chassis modules to generate a new family of products.

The above detailed description of the invention has been provided for the purposes of illustration and description. Although the present invention has been described with respect to a specific embodiment, various changes and modifications to the embodiment may be suggested to persons of ordinary skill in the art, and it is intended that the present invention encompass such changes and modifications as fall within the scope of the claims appended hereto.

What is claimed is:

1. A digital television architecture, comprising:
a processing chassis operative to convert an analog input signal into at least a first digital signal for use in providing information to be provided to a user, the processing chassis including a dedicated power source and processing element;
a presentation chassis operative to convert audio and visual components of the at least first digital signal into a final signal for presentation on a display, the audio and visual conversion being performed in a first domain, the presentation device chassis being separate from the processing chassis and including a dedicated power source of the presentation chassis being different from the power source of the processing chassis; and
an interface operative to provide a communication path between the processing chassis and the presentation chassis.

2. The digital television of claim 1, wherein the interface includes a digital video interface.

3. The digital television of claim 1, wherein the processing chassis further includes an audio interface for converting audio signals contained within the input signal into a digital signal.

4. The digital television of claim 3, wherein the processing chassis further includes a video interface for converting the video signal contained within the input signal to high resolution digital signal.

5. The digital television of claim 1, wherein the processing chassis includes a power source and the presentation chassis includes a power source, the power source of the processing chassis providing power to the processing chassis independent of the power being supplied to the presentation chassis.

6. The digital television of claim 1, wherein the display device is a monitor.

7. The digital television of claim 1, wherein the input signal is provided to the processing chassis by one of the following:
a terrestrial antenna, a cable connection, and a satellite connection.

8. The digital television of claim 6, wherein the monitor is a CRT.

9. A modular television architecture, comprising:
a processing module including circuitry operative to convert an input signal from a first type into at least a second type, the conversion being performed in the digital domain;
a presentation module operative to convert audio and visual information contained within the at least second signal into a final signal for presentation on a display device, the audio and visual conversion being performed in a first domain, the presentation module being separate from and operating independently of the processing module; and
an interface operative to provide a communication path between the processing module and the presentation module

10. The modular television of claim 9, wherein the processing module further includes a power source and a format converter and the presentation module further includes a power source, wherein the power source of the processing module is independent of the power source of the presentation module.

11. A television system, comprising:
a processing module for providing signals that represent information to be provided on a suitable display device;
a presentation module including decoding and filtering elements, operative to process the signals provided by the processing module and display the images represented thereby on the display device; and
an interface module for coupling the processing module and the presentation module together, wherein the processing and presentation modules operate independently from one another and the processing performed by the processing module is performed in the digital domain.

12. The system of claim 11, wherein the display device is a monitor.

13. The modular television of claim 11, wherein the processing module further includes a power source and a line doubler and the presentation module further includes a power source, wherein the power source of the processing module is independent of the power source of the presentation module.
